(19) United States
(12) Patent Application Publication
(10) Pub. No.: US 2007/0158637 A1
(43) Pub. Date: Jul. 12, 2007

(54) Semiconductor laser device

(75) Inventor: Akira Tanaka, Kanagawa-ken (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: Kabushiki Kaisha Toshiba, Minato-ku (JP)

(21) Appl. No.: 11/347,658

(22) Filed: Feb. 6, 2006

(30) Foreign Application Priority Data
Jan. 6, 2006 (JP) 2006-022171

(51) Int. Cl. H01L 31/00

(52) U.S. Cl. 257/12

(57) ABSTRACT

A semiconductor laser device comprises: a first cladding layer provided on a substrate, the first cladding layer being made of nitride semiconductor of a first conductivity type; an active layer provided on the first cladding layer, the active layer being made of a quantum well structure using nitride semiconductor; and a second cladding layer provided on the active layer, the second cladding layer having a ridge waveguide and being made of nitride semiconductor of a second conductivity type. The first cladding layer is made of Al_{Z}Ga_{1-Z}N having an aluminum composition ratio Z of 0.04 or less and has a thickness of not less than 1.6 μm.

### CROSS-REFERENCE TO RELATED APPLICATIONS

This application is based upon and claims the benefits of priorities from the prior Japanese Patent Application No. 2006-22171, filed on Jan. 31, 2006; the entire contents of which are incorporated herein by reference.

### BACKGROUND OF THE INVENTION

In the next generation DVD (Digital Versatile Disc) including high-definition image recording, wavelengths in the 400-nanometer band are used to achieve a recording capacity of 15 to 20 gigabytes in a single-sided single-layer medium.

In general, DVD applications using wavelengths in the 650-nanometer band, rather than CD applications using wavelengths in the 780-nanometer band, are more demanding on reduction of aberration and precision of optical axis alignment in the optical system because the associated beam spot size is smaller. For similar reasons, the next generation DVD applications using wavelengths in the 400-nanometer band will impose even stricter requirements on the optical system. Therefore, stricter specifications are required for the beam from a semiconductor laser device, especially for its FFP (Far Field Pattern).

Nitride semiconductor is used to emit wavelengths in the 400-nanometer band. One of the features of nitride semiconductor is that the lattice constant greatly differs depending on its composition. When a semiconductor laser device is constructed from such nitride semiconductor, the composition and thickness of various layers intended for appropriate optical confinement to the active layer, optical guide layer, and cladding layer are limited by crystalline degradation (e.g., crack) due to lattice mismatch. That is, when the lattice constant differs greatly, cracks or the like may occur in a grown film with greater film thickness.

For example, if AlᵣGa₁₋ᵣN cladding layers (0≦r≦1) for optical confinement, which sandwich the active layer that emits wavelengths in the 400-nanometer band, can be made thicker, then adverse effects such as reflection at the outside of the cladding layers could be suppressed. However, AlGaN has a smaller lattice constant than GaN and InGaN, and has an upper limit on the film thickness of its growth.

Moreover, it is possible to increase the Al composition ratio to decrease the refractive index and enhance optical confinement. At the same time, however, there is a problem that the lattice constant is decreased and crystallinity is all the more degraded. Furthermore, excessively strong optical confinement also causes a problem that the vertical FFP is too large, which makes it difficult to satisfy optical specifications.

### SUMMARY OF THE INVENTION

According to an aspect of the invention, there is provided a semiconductor laser device comprising: a semiconductor laser device comprising: a first cladding layer provided on a substrate, the first cladding layer being made of nitride semiconductor of a first conductivity type; an active layer provided on the first cladding layer, the active layer being made of a quantum well structure using nitride semiconductor; and a second cladding layer provided on the active layer, the second cladding layer having a ridge waveguide and being made of nitride semiconductor of a second conductivity type, the first cladding layer being made of Al_{z}Ga_{1-z}N having an aluminum composition ratio z of 0.04 or less and having a thickness of not less than 1.6 μm.

According to other aspect of the invention, there is provided a semiconductor laser device comprising: a first cladding layer provided on a substrate, the first cladding layer being made of nitride semiconductor of a first conductivity type; an active layer provided on the first cladding layer, the active layer being made of a quantum well structure using nitride semiconductor; and a second cladding layer provided on the active layer, the second cladding layer having a ridge waveguide and being made of nitride semiconductor of a second conductivity type, the first cladding layer being made of Al_{z}Ga_{1-z}N (0≦z≦1) having an aluminum composition ratio z of 0.04 or less and having a thickness of not less than 1.6 μm, the second cladding layer including either a superlattice layer having an average aluminum composition ratio w of 0.04 or less in which GaN and Al_{w}Ga_{1-w}N (0≦w≦1) are alternately laminated, or AlₚGa₁₋ₚN having an aluminum composition ratio p of 0.04 or less, and the ridge waveguide having a height of not more than 0.45 μm.

According to other aspect of the invention, there is provided a semiconductor laser device comprising: a first cladding layer provided on a substrate, the first cladding layer being made of nitride semiconductor of a first conductivity type; an active layer provided on the first cladding layer, the active layer being made of a quantum well structure using nitride semiconductor; and a second cladding layer provided on the active layer, the second cladding layer having a ridge waveguide and being made of nitride semiconductor of a second conductivity type, the first cladding layer being made of a superlattice layer having an average aluminum composition ratio s of 0.04 or less in which GaN and AlₛGa₁₋ₛN (0≦s≦1) are alternately laminated, and the first cladding layer having a thickness of not less than 1.6 μm.

### BRIEF DESCRIPTION OF THE DRAWINGS

FIG. 1 is a schematic cross section of a semiconductor laser device according to an example of the invention;

FIG. 2 is an energy band diagram of the semiconductor laminated structure of the semiconductor laser device illustrated in FIG. 1;

FIG. 3 is a diagram for illustrating the FFP of a beam emitted from the semiconductor laser device;

FIG. 4 is a graphical diagram showing measured values of the vertical FFP of the example;

FIG. 5 is a graphical diagram showing measured values of the vertical FFP of a first comparative example;

FIG. 6 is a graphical diagram in which a subpeak in the vertical FFP is analyzed by simulation;

FIG. 7 is a partially enlarged graphical diagram of region A in FIG. 6; and

FIG. 8 is a graphical diagram showing a simulation result regarding ridge height dependence of operating current at an optical power of 80 mW.

### DETAILED DESCRIPTION OF THE INVENTION

Embodiments of the invention will now be described with reference to the drawings.

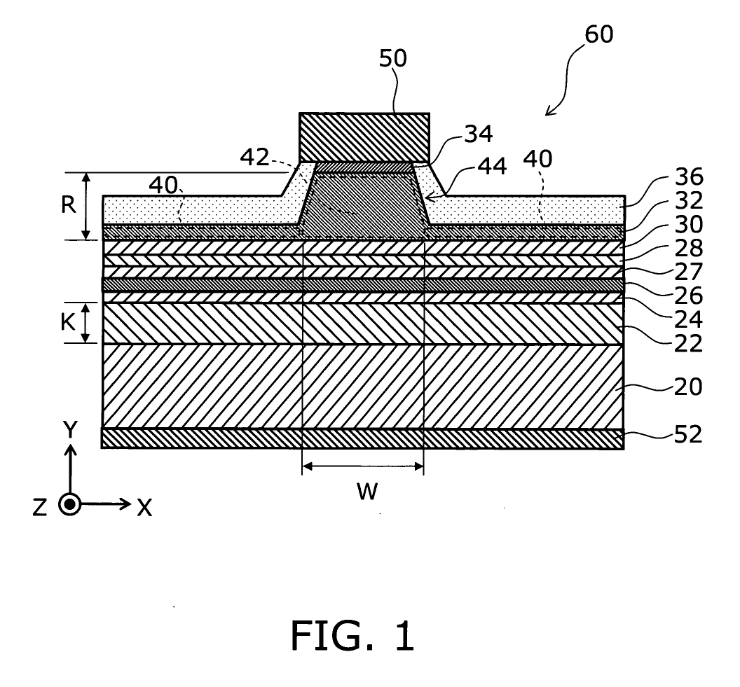

FIG. 1 is a schematic cross section of a nitride semiconductor laser device 60 according to an example of the invention.

On an n-type GaN substrate 20, an n-type Al_{0.04}Ga_{0.96}N cladding layer 22 (with a thickness of 2.0 μm), an n-type GaN optical guide layer 24 (with a thickness of 0.07 μm), and an active layer 26 are laminated.

On the active layer 26, a non-doped GaN diffusion blocking layer 27 (with a thickness of 0.05 μm), a p⁺-type Al_{0.20}Ga_{0.80}N overflow blocking layer 28 (with a thickness of 10 nm), a p-type GaN optical guide layer 30 (with a thickness of 0.03 μm), a p-type Al_{0.04}Ga_{0.96}N cladding layer 32 (with a thickness of 0.4 μm), and a p⁺-type GaN contact layer 34 (with a thickness of 0.10 μm) are laminated. These semiconductor laminated films can be sequentially grown on the n-type GaN substrate 20 by, for example, MOCVD (Metal Organic Chemical Vapor Deposition) method. Note that typically, silicon is used as n-type impurities and magnesium is used as p-type impurities.

Note that the “nitride semiconductor” used herein includes semiconductors having any composition represented by the chemical formula InₘAlₙGa₁₋ₘ₋ₙN (0≦m≦1, 0≦n≦1, m+n≦1) where the composition ratios m and n are varied in the respective ranges. Furthermore, the “nitride semiconductor” also includes those further containing any of various impurities added for controlling conductivity types.

The structure illustrated in FIG. 1 belongs to a refractive index waveguide structure called “ridge waveguide type”. More specifically, the p-type AlGaN cladding layer 32 has a ridge portion 42 with height R represented by dashed line and a non-ridge portion 40 represented by dashed line. Note that in the first example, the height R of the ridge portion 42 is 0.40 μm and the height of the non-ridge portion 40 is 0.05 μm. The p⁺-type GaN contact layer above the ridge portion 42 is patterned at the same time. An insulating film 36 is formed on the p⁺-type GaN contact layer 34 side face and a ridge side face 44 of the ridge portion 42 that are patterned. The insulating film 36 can be made of material such as SiO₂ or Si₃N₄. Note that SiO₂ has a refractive index of about 1.5 and Si₃N₄ has a refractive index of 1.9 to 2.1.

The p⁺-type GaN contact layer 34 is connected to a p-side electrode 50 made of monolayer, lamination, or alloy of Pt, Pd, Ni, or Au, for example. The n-type GaN substrate 20 is connected to an n-side electrode 52 made of monolayer, lamination, or alloy of Ti, Pt, Au, or Al. The p⁺-type GaN contact layer 34 serves to decrease contact resistance between the p-type AlGaN cladding layer 32 and the p-side electrode 50, thereby decreasing operating voltage.

Since an insulating film 36 is provided on the ridge side face 44 of the ridge portion 42, a difference occurs between the refractive index of the p-type AlGaN cladding layer 32 constituting the ridge portion 42 and that of the insulating film 36. The p-type AlGaN cladding layer 32 has a refractive index of about 2.523 because it has a composition of Al_{0.04}Ga_{0.96}N.

Since the refractive index of the ridge portion 42 is thus higher than that of the insulating film 36, the fundamental horizontal transverse mode is confined horizontally (X axis) relative to the active layer 26 in the cross section orthogonal to the optical axis (parallel to the Z axis). However, if the width W of the ridge portion 42 at its bottom is too large as compared to the wavelength, higher order modes may occur in the horizontal transverse mode. It is preferable to select the width W of the ridge portion 42 to be 1 to 3 μm. In this example, it is set to 1.5 μm. As a result, higher order modes can be suppressed. The thickness of the ridge portion 42 is set to 0.40 μm.

Next, the function of the laminated structure will be described in more detail.

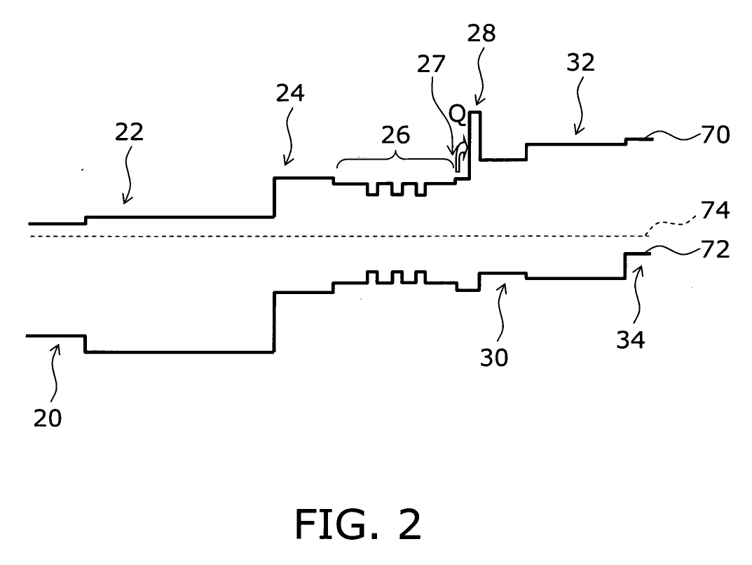

FIG. 2 is an energy band diagram of the semiconductor laminated structure of this example.

The conduction band 70 and the valence band 72 in various layers are represented with reference to the quasi-Fermi level 74. The non-doped GaN diffusion blocking layer 27 prevents p-type impurities such as magnesium (Mg), for example, from diffusing from the highly concentrated, p⁺-type AlGaN overflow blocking layer 28 into the active layer 26.

It can also be understood from FIG. 2 that the p⁺-type overflow blocking layer 28 can suppress unnecessary increase of operating current due to leakage of electrons Q, injected from the n-type GaN substrate 20 side, into the p-type Al_{0.04}Ga_{0.96}N cladding layer 32, as indicated by an arrow.

More specifically, a higher Al (aluminum) composition ratio of the p⁺-type AlGaN overflow blocking layer 28 increases its band gap difference relative to the active layer 26, which can prevent electrons Q injected from the n-side from leaking from the active layer 26 into the p-type Al_{0.04}Ga_{0.96}N cladding layer 32. Preferably, the Al composition ratio is 0.20 or more. Moreover, since the heterobarrier on the conduction band side relative to the active layer 26 can be increased by increasing the p-type concentration (e.g., 1×10²⁰ cm⁻³) of the p⁺-type AlGaN overflow blocking layer 28, the leakage of electrons Q can be further reduced. Preferably, the thickness of the p⁺-type AlGaN overflow blocking layer 28 is set to not more than 20 nm (nanometers) in order to avoid degradation of crystallinity.

The active layer 26, made of InₓGa₁₋ₓN/In_{y}Ga_{1-y}N, can be a single quantum well or multiple quantum well active layer. In this case, the In (indium) composition ratio x in the well layer can be selected within the range of 0.05 to 0.2, and the In composition ratio y in the barrier layer can be selected within the range of 0 to 0.05. The thickness of the well layer can be 2 to 5 nm, the number of wells can be two to four, and the thickness of the barrier layer can be 3 to 10 nm. In this example, the structure of In_{0.13}Ga_{0.87}N/In_{0.01}Ga_{0.99}N is selected, and the thickness of the well layer is 3 nm, the number of wells is three, and the thickness of the barrier layer is 5 nm. According to this structure, the oscillation wavelength can be set within the range of 405±5 nm. The composition and profile of the active layer can be varied to adjust the threshold current, FFP (Far Field Pattern), temperature characteristic, and the like.

The Al composition ratio of the n-type Al_{0.04}Ga_{0.96}N cladding layer 22 and the p-type Al_{0.04}Ga_{0.96}N cladding layer 32 is not limited to 0.04, but can be set to 0.04 or less. Instead of such a bulk structure, it can be a superlattice layer in which Al_{q}Ga_{1-q}N (0≦q≦1) and GaN are alternately laminated. In this case, preferably, the thickness of each layer is selected within the range of 1 to 5 nm, and the average Al composition ratio is 0.04 or less for maintaining crystallinity. Such a superlattice layer can alleviate stress to the crystal due to lattice mismatch.

Next, the FFP of a beam emitted from a semiconductor laser device will be described, which is important in the next generation DVD or other applications.

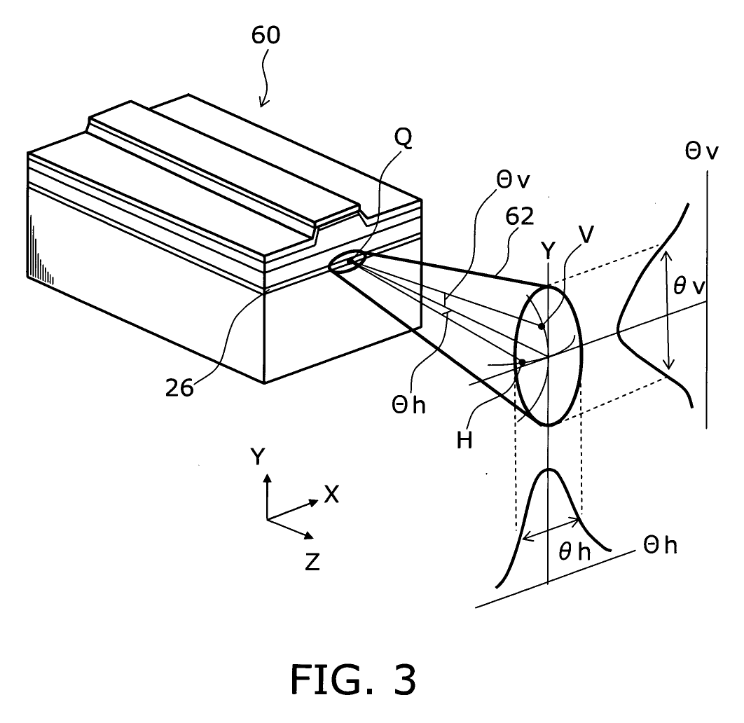

FIG. 3 is a diagram for illustrating the FFP. A beam 62 is emitted along the Z axis from one end face of a semiconductor laser device 60.

The beam 62 emitted from an emission point Q on an end face of the active layer 26 spreads out both horizontally (X) and vertically (Y). Through measurement of beam optical intensity by placing a photodiode at point V on a circle in a vertical plane centered on the emission point Q and directing its light receiving surface to Q, an FFP is obtained that is the optical intensity distribution at angle Θv in the vertical plane. The full angle at half maximum, that is, the angle at which the optical intensity is half its maximum, is referred to as beam spread angle (θv).

Similarly, through measurement of beam optical intensity by placing a photodiode at point H on a circle in a horizontal plane centered on the emission point Q and directing its light receiving surface to Q, an FFP is obtained that is the optical intensity distribution at angle Θh in the horizontal plane. Beam spread angle (θh), which is its full angle at half maximum, is thus obtained.

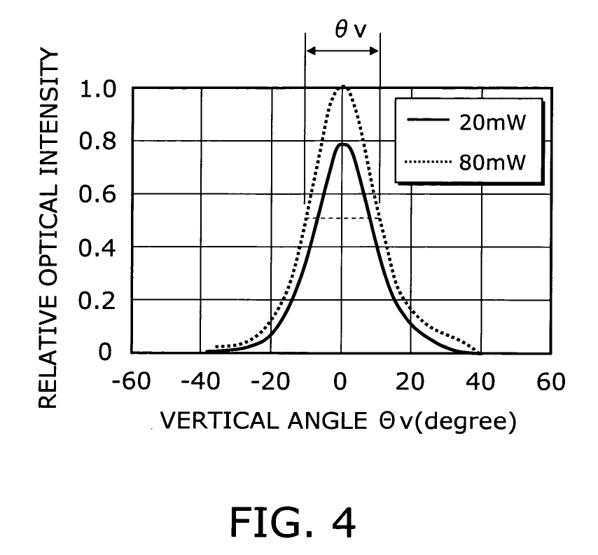

FIG. 4 is a graphical diagram showing measured values of the vertical FFP in this example. The vertical axis indicates the relative optical intensity, and the horizontal axis indicates the vertical angle Θv illustrated in FIG. 3. The solid line represents the FFP for an optical power of 20 mW, and the dashed line represents the FFP for an optical power of 80 mW. The vertical spread angle θv, which is the full angle at half maximum, is about 22 degrees for both of the optical powers, and has good vertical symmetry. The range of 18 to 24 degrees is preferable for the next generation DVD specifications, which is well satisfied by the first example. The measured values of the horizontal FFP, although not shown, have a pattern with no subpeak. Its full angle at half maximum, θh, is about 9 degrees, which is within the range of 7 to 9 degrees required by the next generation DVD specifications.

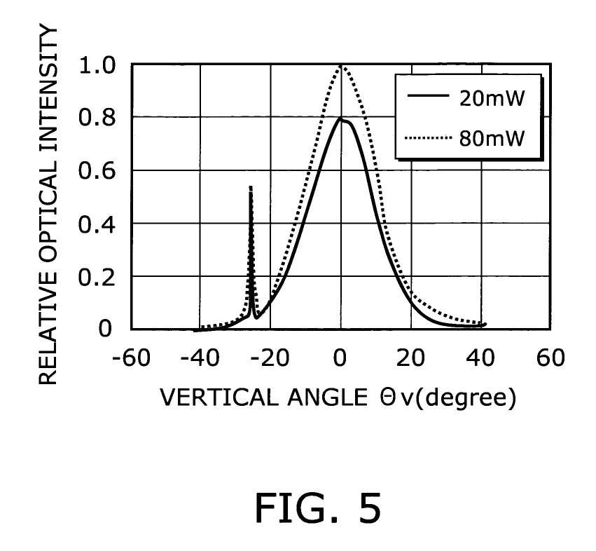

FIG. 5 is a graphical diagram showing measured values of the vertical FFP of a semiconductor laser device according to a first comparative example in which the thickness of the n-type AlGaN cladding layer 22 is 1.5 μm.

The structure is the same as that of the present example except for the thickness of the n-type AlGaN cladding layer 22. In the first comparative example, a subpeak occurs near −27 degrees both at a power of 20 mW indicated by the solid line and at a power of 80 mW indicated by the dashed line. In this case, the beam spread angle can be regarded as about 22 degrees except for the subpeak. However, it is determined that the beam does not exhibit a proper distribution in the cross section when a subpeak with intensity greater than half the maximum optical intensity occurs near 27 degrees.

This subpeak, which occurs near Θv of −27 degrees, may be nonuniform on this Θv, exhibiting further partial concentration of optical intensity. Such a partial emission subpeak can be examined by two-dimensional detection of FFP.

Typically, in an optical system for recording applications, an elliptical cross-sectional beam is transformed close to a circular cross-sectional beam by being passed through a triangular prism and/or a cylindrical lens in order to make the best use of beam power. The optical distribution of such a shaped beam is assumed to be a Gaussian distribution, for example, for optical design. Therefore, a beam having a strong subpeak is undesirable because it may cause errors in tracking, focus detection, or signal detection.

In contrast, the subpeak is suppressed in the FFP according to the example illustrated in FIG. 4. Therefore, for example, a beam incident on a multi-division photodiode has an optical distribution close to a Gaussian distribution. As a result, any deviation in focusing and tracking can be accurately detected from the increase and decrease of photocurrent caused by light incident on each element of the multi-division photodiode.

In a phase-change optical disk used for DVD recording, it is necessary to change laser power between the crystallizing level for the erased state and the amorphizing level for the recorded state. In this case, the laser light spot is narrowed to enclose a recording mark. Therefore, if there is any partially high-power region like the subpeak in the comparative example, uniform crystallization and amorphization in the recording mark region may fail, which is undesirable. Note that in the next generation DVD recording, a pulse optical power of 120 mW or more is required for writing and a pulse optical power of 80 mW or more is required for erasing. These are optical power levels required of a semiconductor laser device. Actual optical power of a light on an optical disk will be lower.

Next, the cause of the subpeak in the vertical FFP in the first comparative example illustrated in FIG. 5 will be discussed. Light that has leaked from the n-type AlGaN cladding layer 22 is incident on and reflected from the transparent n-type GaN substrate 20, causing interference of light.

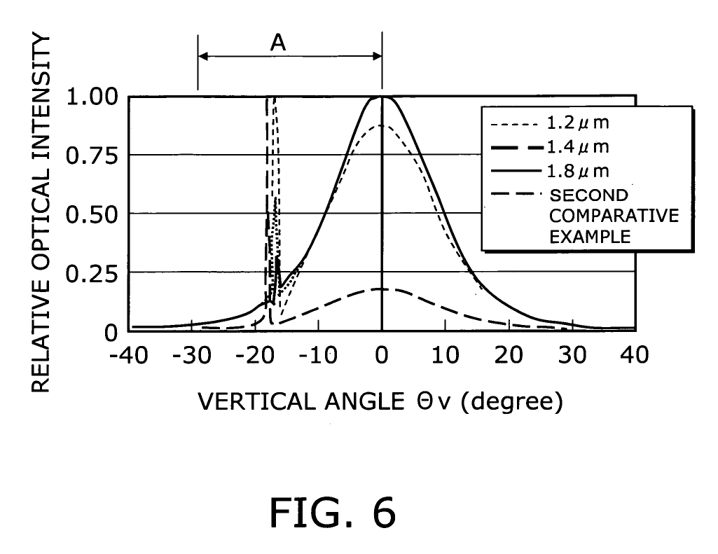

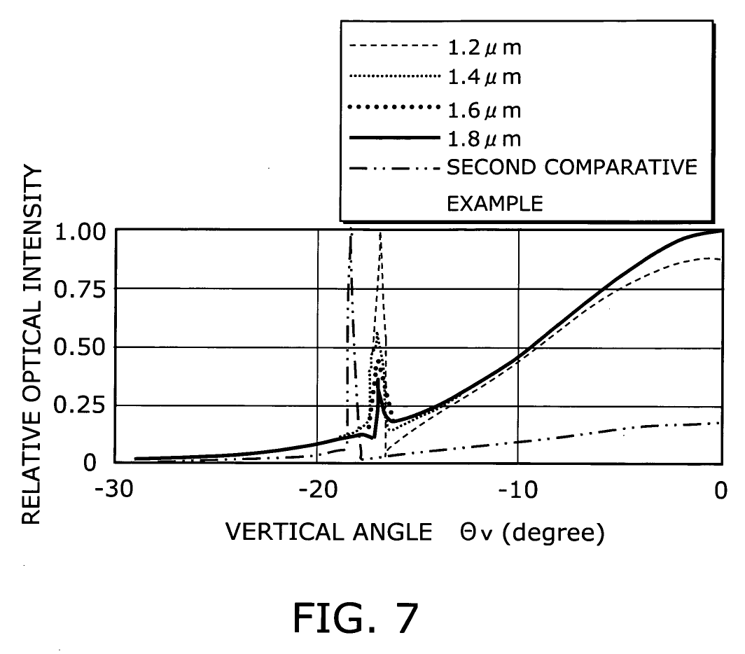

FIGS. 6 and 7 are graphical diagrams showing the result of analyzing this by simulation. Here the thickness K of the n-type AlGaN cladding layer 22 is taken as a parameter, which is set to 1.2, 1.4, 1.6, and 1.8 μm. The remaining structure is the same as that of the first example. The structure of a second comparative example is different from that of the first example only in its n-type Al_{0.05}Ga_{0.95}N cladding layer (thickness of 1.2 μm) and p-type Al_{0.05}Ga_{0.95}N cladding layer (thickness of 0.5 μm), and the remaining structure is the same.

In FIG. 6, the vertical axis indicates the relative optical intensity, and the horizontal axis indicates the vertical angle Θv (degree). When the thickness K of the n-type AlGaN cladding layer 22 is 1.2 μm, a large subpeak occurs within the range of Θv from −18.5 to −17 degrees. The large subpeak is also observed in the second comparative example. These subpeaks are larger than that at Θv=0. In order to compare the vicinity of the subpeak in FIG. 6 in more detail, FIG. 7 shows a graphical diagram in which region A with Θv of −30 to 0 degrees is enlarged.

In FIG. 7, in each simulation example where the thickness K of the n-type AlGaN cladding layer 22 is taken as a parameter, a subpeak occurs near −17 degrees. For K=1.2 μm, the optical intensity is larger at the subpeak than at Θv=0.

The optical intensity of the subpeak decreases as the thickness K of the n-type AlGaN cladding layer 22 successively increases to 1.4, 1.6, and 1.8 μm. For K not less than 1.6 μm, the subpeak can be reduced to half the maximum (the value at Θv=0), which can satisfy the next generation DVD optical specifications.

In the second comparative example, the subpeak is even larger, and the relative optical intensity at Θv=0 is about 0.2. The subpeak occurrence angle is slightly displaced to the vicinity of −18.5 degrees because of the difference of the composition of n-type AlGaN. In contrast to the second comparative example, the simulation example with K=1.2 μm achieves reduction of the disturbance of FFP through the effect of decreasing the Al composition ratio of the n-type AlGaN cladding layer 22 and the p-type AlGaN cladding layer 32 to 0.04 and decreasing the ridge height R of the p-type AlGaN cladding layer 32 to 0.40 μm.

In nitride semiconductor, as the Al composition ratio increases, the lattice constant decreases, which impairs crystallinity due to occurrence of cracks or the like. This makes it difficult to grow thick film. However, at the same time, since the refractive index decreases, strong optical confinement can be achieved in general. The above simulation result shows that the disturbance of FFP or subpeak on the substrate side (Θv≦0) can be suppressed by setting the Al composition ratio to 0.04 or less for avoiding excessively strong optical confinement (i.e., setting θv≦24°) and setting the thickness of the n-type AlGaN cladding layer to not less than 1.6 μm. When the Al composition ratio is 0.04, the film thickness of the n-type Al_{0.04}Ga_{0.96}N cladding layer 22 up to 2.5 μm can ensure crystallinity that enables the operation of a semiconductor laser device.

It is contemplated that the Al composition ratio of the p-type AlGaN cladding layer 32 being set to 0.04, which is smaller than 0.05 of the second comparative example, may cause overflow in which carriers fail to recombine in the active layer and leak into the p-type AlGaN cladding layer 32. However, the Al composition ratio in the p⁺-type AlGaN overflow blocking layer 28 being set to 0.20 or more can suppress the overflow. In this case, the refractive index difference relative to GaN can be reduced by decreasing the Al composition ratio. As a result, disturbance of the vertical FFP caused by the p⁺-type GaN contact layer 34 can also be reduced.

Next, the Al composition ratio and the thickness of the p-type AlGaN cladding layer 32 on the ridge side (Θv>0) will be described. The shape of the ridge portion 42 is important because it determines the operating current of the semiconductor laser device 60. While low-current operation is required to obtain higher power, the structure is determined in view of optical confinement (i.e., FFP), and a leakage of waveguiding modes into the p⁺-type GaN contact layer 34.

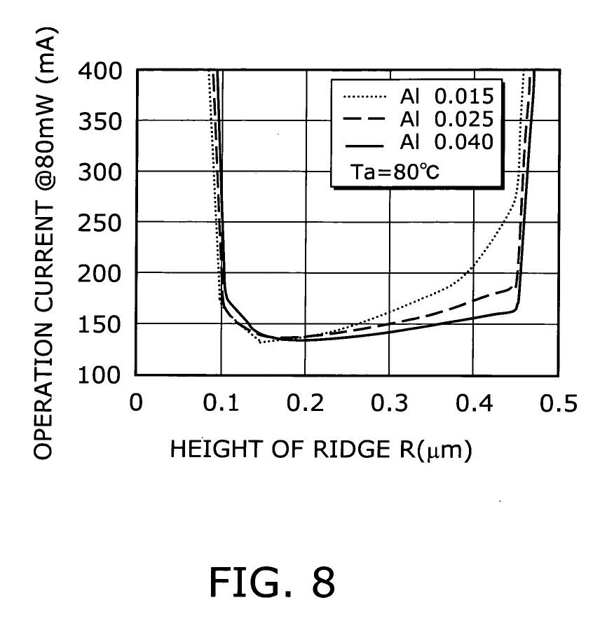

FIG. 8 is a graphical diagram showing a result of analyzing by simulation the dependence of operating current at a power of 80 mW on the height R of the ridge portion 42 (Ta=80° C.).

The Al composition ratio k of p-type AlₖGa₁₋ₖN (0≦k≦1) constituting the ridge portion 42 is taken as a parameter, which is selected to be 0.015, 0.025, and 0.040. The bottom width W of the ridge portion 42 is set to 1.5 μm. The remaining structure is the same as the present example except for the Al composition ratio y and the height R of the ridge portion 42.

Reduction of operating current at a power of 80 mW is achieved as the Al composition ratio increases from 0.015. When the height R of the ridge portion 42 is smaller than 0.1 μm, the operating current increases because it is hard to control the horizontal transverse mode. When the height R of the ridge portion 42 is 0.45 μm or more, the operating current increases because lateral current is difficult to confine. For this reason, the upper limit of the height R of the ridge portion 42 is set to 0.45 μm. The upper limit of the Al composition ratio y is set to 0.040, which enables good crystallinity to be maintained.

Such a structure of the ridge portion 42 can achieve good FFP as illustrated in FIG. 4. On the other hand, if the cladding layer is composed of p-type Al_{0.08}Ga_{0.92}N, for example, the refractive index of the p⁺-type GaN contact layer 34 becomes even larger than that of the p-type AlGaN cladding layer 32, which causes the protruded waveguiding modes to further penetrate vertically into the p⁺-type GaN contact layer 34. As a result, the vertical FFP is disturbed and a subpeak is likely to occur near Θv of +10 degrees, for example. However, by setting the average the Al composition ratio to 0.04 or less and the height R of the ridge portion 42 to not more than 0.45 μm, a semiconductor laser device capable of suppressing subpeaks also on the ridge side can be provided.

Embodiments of the invention have been described with reference to examples. However, the invention is not limited to these examples. For example, while the invention has been described with reference to a nitride semiconductor laser device, the invention is applicable to a wide variety of nitride semiconductor laser devices. Moreover, the substrate is not limited to GaN, but sapphire, SiC, and the like can be used therefor.

Any shape, size, material, and arrangement of various elements constituting the semiconductor laser device that are variously adapted by those skilled in the art are also encompassed within the scope of the invention as long as they include the features of the invention.

1. A semiconductor laser device comprising:
a first cladding layer provided on a substrate, the first cladding layer being made of nitride semiconductor of a first conductivity type;
an active layer provided on the first cladding layer, the active layer being made of a quantum well structure using nitride semiconductor; and
a second cladding layer provided on the active layer, the second cladding layer having a ridge waveguide and being made of nitride semiconductor of a second conductivity type,
the first cladding layer being made of Al_{Z}Ga_{1-Z}N having an aluminum composition ratio z of 0.04 or less and having a thickness of not less than 1.6 μm.

2. A semiconductor laser device according to claim 1, further comprising a carrier overflow blocking layer provided between the active layer and the second cladding layer, the carrier overflow blocking layer being made of nitride semiconductor of the second conductivity type.

3. A semiconductor laser device according to claim 2, wherein the carrier overflow blocking layer has a thickness of not more than 20 nm, and is made of AlGaN having an aluminum composition ratio of 0.20 or more.

4. A semiconductor laser device according to claim 1, further comprising a contact layer provided on the second cladding layer, the contact layer being made of GaN of the second conductivity type.

5. A semiconductor laser device according to claim 1, wherein the active layer is composed of a quantum well structure in which one or more well layers made of InₓGa₁₋ₓN (0.05≦x≦0.2) and one or more barrier layers made of In_{y}Ga_{1-y}N (0≦y≦0.05) are laminated.

6. A semiconductor laser device according to claim 1, wherein laser light emitted from the active layer has a wavelength in a range of 405±5 nm.

7. A semiconductor laser device comprising:
a first cladding layer provided on a substrate, the first cladding layer being made of nitride semiconductor of a first conductivity type;
an active layer provided on the first cladding layer, the active layer being made of a quantum well structure using nitride semiconductor; and
a second cladding layer provided on the active layer, the second cladding layer having a ridge waveguide and being made of nitride semiconductor of a second conductivity type,
the first cladding layer being made of Al_{z}Ga_{1-z}N (0≦z≦1) having an aluminum composition ratio z of 0.04 or less and having a thickness of not less than 1.6 μm,
the second cladding layer including either a superlattice layer having an average aluminum composition ratio w of 0.04 or less in which GaN and Al_{w}Ga_{1-w}N (0≦w≦1) are alternately laminated, or AlₚGa₁₋ₚN having an aluminum composition ratio p of 0.04 or less, and
the ridge waveguide having a height of not more than 0.45 μm.

8. A semiconductor laser device according to claim 7, further comprising a carrier overflow blocking layer provided between the active layer and the second cladding layer, the carrier overflow blocking layer being made of nitride semiconductor of the second conductivity type.

9. A semiconductor laser device according to claim 8, wherein the carrier overflow blocking layer has a thickness of not more than 20 nm, and is made of AlGaN having an aluminum composition ratio of 0.20 or more.

10. A semiconductor laser device according to claim 7, further comprising a contact layer provided on the second cladding layer, the contact layer being made of GaN of the second conductivity type.

11. A semiconductor laser device according to claim 7, wherein the active layer is composed of a quantum well structure in which one or more well layers made of InₓGa₁₋ₓN (0.05≦x≦0.2) and one or more barrier layers made of In_{y}Ga_{1-y}N (0≦y≦0.05) are laminated.

12. A semiconductor laser device according to claim 7, wherein laser light emitted from the active layer has a wavelength in a range of 405±5 nm.

13. A semiconductor laser device comprising:
a first cladding layer provided on a substrate, the first cladding layer being made of nitride semiconductor of a first conductivity type;
an active layer provided on the first cladding layer, the active layer being made of a quantum well structure using nitride semiconductor; and
a second cladding layer provided on the active layer, the second cladding layer having a ridge waveguide and being made of nitride semiconductor of a second conductivity type,
the first cladding layer being made of a superlattice layer having an average aluminum composition ratio s of 0.04 or less in which GaN and AlₛGa₁₋ₛN (0≦s≦1) are alternately laminated, and the first cladding layer having a thickness of not less than 1.6 μm.

14. A semiconductor laser device according to claim 13, further comprising a carrier overflow blocking layer provided between the active layer and the second cladding layer, the carrier overflow blocking layer being made of nitride semiconductor of the second conductivity type.

15. A semiconductor laser device according to claim 14, wherein the carrier overflow blocking layer has a thickness of not more than 20 nm, and is made of AlGaN having an aluminum composition ratio of 0.20 or more.

16. A semiconductor laser device according to claim 13, further comprising a contact layer provided on the second cladding layer, the contact layer being made of GaN of the second conductivity type.

17. A semiconductor laser device according to claim 13, wherein the active layer is composed of a quantum well structure in which one or more well layers made of InₓGa₁₋ₓN (0.05≦x≦0.2) and one or more barrier layers made of In_{y}Ga_{1-y}N (0≦y≦0.05) are laminated.

18. A semiconductor laser device according to claim 8, wherein
the second cladding layer includes either a superlattice layer having an average aluminum composition ratio p of 0.04 or less in which GaN and AlₚGa₁₋ₚN (0≦p≦1) are alternately laminated, or Al_{w}Ga_{1-w}N having an aluminum composition ratio w of 0.04 or less, and
the ridge waveguide has a height of not more than 0.45 μm.

19. A semiconductor laser device according to claim 18, further comprising a carrier overflow blocking layer provided between the active layer and the second cladding layer.

20. A semiconductor laser device according to claim 19, wherein the carrier overflow blocking layer has a thickness of not more than 20 nm, and is made of AlGaN having an aluminum composition ratio of 0.20 or more.
